(19) United States
(12) Patent Application Publication
(10) Pub. No.: US 2026/0349408 A1
(43) Pub. Date: Nov. 5, 2026

(54) DUMMY FILL FOR DYNAMIC DIGITIAL CONNECTION (DDC) IN DIGITAL LITHOGRAPHY

(71) Applicant: Applied Materials, Inc., Santa Clara, CA (US)

(72) Inventors: Chung-Shin KANG, San Jose, CA (US); Yinfeng DONG, San Jose, CA (US); Thomas L. LAIDIG, Richmond, CA (US)

(21) Appl. No.: 19/131,057

(22) PCT Filed: Dec. 27, 2023
(86) PCT No.: PCT/US2023/086085

§ 371 Date: May 19, 2025

Related U.S. Application Data
(60) Provisional application No. 63/435,495, filed on Dec. 27, 2022.

(51) Int. Cl. G05B 19/4099

(52) U.S. Cl. CPC G05B 19/4099; G05B 2219/45031

(57) ABSTRACT

A system configured to receive a substrate layout design; generate a digital exposure group based on the substrate and the chip group package layout design; pattern onto a substrate both the substrate and the associated chip group dummy fill connection points utilizing the digital exposure group; detect the disposition of the substrate and the associated chip group dummy fill connection points on the substrate; determine a modified dummy fill pixel model interconnection segment configured couple the substrate and the associated chip group dummy fill connection points based upon the disposition of the substrate and the associated chip group dummy fill connection points on the substrate; and pattern onto the substrate a modified dummy fill interconnection segment such that the substrate and the associated chip group dummy fill connection points on the substrate are coupled utilizing dummy fill based upon the modified dummy fill pixel model interconnection segment.

### BACKGROUND

As demand for additional functionality of semiconductor devices increases, heterogeneously integrating modules that enable this additional functionality becomes an increasingly large factor in semiconductor manufacturing. Integrated modules may include and are not limited to memory, sensors, logic, antennas, display drivers, controllable drivers and the like. In this context, an integrated module may be a separately manufactured semiconductor product that is placed on a substrate or a design that is fabricated to the substrate by a separate process.

### SUMMARY

In one embodiment, a system is disclosed. The system includes a memory containing computer-readable program code and a processor. The processor is interoperably coupled with the memory. The processor is configured to receive a substrate layout design. The substrate layout design includes a substrate dummy fill connection point and a chip group package layout design. The chip group package layout design includes an associated chip group dummy fill connection point. The processor is further configured to generate a digital exposure group based on the substrate and the chip group package layout designs. The processor then patterns, using a pattering tool for the system, onto a substrate both the substrate and the associated chip group dummy fill connection points utilizing the digital exposure group. The processor detects, using a metrology source, the disposition of the substrate and the associated chip group dummy fill connection points on the substrate. The processor further determines using a trained machine learning (ML) model, a modified dummy fill pixel model interconnection segment configured to couple the substrate and the associated chip group dummy fill connection points based upon the disposition of the substrate and the associated chip group dummy fill connection points on the substrate. The processor then patterns, using the pattering tool, onto the substrate a modified dummy fill interconnection segment such that the substrate and the associated chip group dummy fill connection points on the substrate are coupled utilizing dummy fill based upon the modified dummy fill pixel model interconnection segment.

In another embodiment, a non-transitory tangible computer-readable storage medium is disclosed. The non-transitory tangible computer-readable storage medium includes stored executable computer code. The computer code includes a set of instructions that causes one or more processors to perform a series of operations. The operations include receiving a substrate layout design including a substrate dummy fill connection point and a chip group package layout design comprising an associated chip group dummy fill connection point. The operations further include generating a digital exposure group based on the substrate and the chip group package layout designs and pattering onto a substrate both the substrate and the associated chip group dummy fill connection points utilizing the digital exposure group. The operations still further include detecting the disposition of the substrate and the associated chip group dummy fill connection points on the substrate and determining a modified dummy fill pixel model interconnection segment. The modified dummy fill pixel model interconnection segment is configured to couple the substrate and the associated chip group dummy fill connection points based upon the disposition of the substrate and the associated chip group dummy fill connection points on the substrate. The operations include patterning onto the substrate a modified dummy fill interconnection segment such that the substrate and the associated chip group dummy fill connection points on the substrate are coupled utilizing dummy fill based upon the modified dummy fill pixel model interconnection segment.

In yet another embodiment, a computer-implemented method is disclosed. The method is executed by one or more processors. The method includes receiving, by one or more processors, a substrate layout design comprising a substrate dummy fill connection point and a chip group package layout design comprising an associated chip group dummy fill connection point. The method generates, by one more processors, a digital exposure group based on the substrate and the chip group package layout designs and patterns, by one more processors, onto a substrate both the substrate and the associated chip group dummy fill connection points utilizing the digital exposure group. The method further detects, by one more processors, the disposition of the substrate and the associated chip group dummy fill connection points on the substrate and determines, by one more processors, a modified dummy fill pixel model interconnection segment. The modified dummy fill pixel model interconnection segment is configured to couple the substrate and the associated chip group dummy fill connection points based upon the disposition of the substrate and the associated chip group dummy fill connection points on the substrate. The method further patterns, by one more processors, onto the substrate a modified dummy fill interconnection segment such that the substrate and the associated chip group dummy fill connection points on the substrate are coupled utilizing dummy fill based upon the modified dummy fill pixel model interconnection segment.

### BRIEF DESCRIPTION OF THE DRAWINGS

So that the manner in which the recited features of the present disclosure can be understood in detail, a more particular description of the disclosure may be had by reference to one or more embodiments, some of which are illustrated in the appended drawings. It is to be noted, however, that the appended drawings illustrate only one or more of the several embodiments; therefore, the one or more embodiments provided in the Drawings are not to be considered limiting of the broadest interpretation of the detailed scope. Other effective embodiments as may be described in the Detailed Description may be considered part of the envisioned detailed scope.

FIG. 1A depicts a substrate layout design, according to one or more embodiments.

FIG. 1B depicts a focused view enhancement of a portion of the substrate layout design, according to one or more embodiments.

FIG. 2A depicts a focus view of a substrate layout design. FIGS. 2B and 2C depict enhanced focus views of the substrate layout design of FIG. 2A showing potential defective features in a common dummy fill structure due to a misaligned chip group.

FIG. 3 depicts a perspective view of a system, according to one or more embodiments.

FIG. 4 depicts a cross-sectional side view of the system of FIG. 3, according to one or more embodiments.

FIG. 5 depicts a schematic diagram of a control system including a controller for a system, according to one or more embodiments.

FIG. 6 depicts a schematic diagram for a machine learning (ML) model, according to one or more embodiments.

FIG. 7 depicts a block diagram of a computer system, according to one or more embodiments.

FIG. 8 depicts a flow diagram for correcting locally dispositioned dummy fill patterns by machine learning (ML)-based dynamic digital corrections, according to one or more embodiments.

FIG. 9A depicts a portion of a substrate layout design, according to one or more embodiments. FIG. 9B depicts a potential result of patterning a substrate layout design on a substrate, according to one or more embodiments. FIG. 9C depicts the detection of the degree of misalignment of the misaligned CG package and its CG dummy fill connection points in relation to each of their associated substrate dummy fill connection points, according to one or more embodiments. FIG. 9D depicts an embodiment mitigated crossover dummy fill pattern with modified dummy fill interconnection segments, according to certain embodiments.

FIG. 10 depicts a second flow diagram for correcting locally dispositioned dummy fill patterns by machine learning (ML)-based dynamic digital corrections, according to one or more embodiments.

FIG. 11A depicts a portion of a substrate layout design, according to one or more embodiments. FIG. 11B depicts part of a potential result of patterning a substrate layout design on a substrate, according to one or more embodiments. FIG. 11C depicts a potential result of patterning a substrate layout design on a substrate, according to one or more embodiments. FIG. 11D depicts the detection of the degree of misalignment of the misaligned CG package and its CG dummy fill connection points in relation to each of their associated substrate dummy fill connection points, according to one or more embodiments. FIG. 11E depicts an embodiment mitigated crossover dummy fill pattern with modified dummy fill interconnection segments, according to certain embodiments.

To facilitate understanding and better appreciation for the described scope, in some instances either identical or associated reference numerals have been used (where possible) to designate identical or similar elements, respectively, that are common in the figures. One of skill in the art may appreciate that elements and features of one embodiment may be beneficially incorporated in one or more other embodiments without further recitation.

### DETAILED DESCRIPTION

In the following, reference is made to one or more embodiments. However, one of skill in the art does appreciate that the disclosure is not limited to specifically described embodiments. Rather, any combination of the following features and elements, whether related to different embodiments or not, is contemplated to implement and practice one or more embodiments provided by the disclosure. Furthermore, although the one or more embodiments presented in the disclosure may achieve advantages over other possible solutions, the prior art (if existing), and combinations thereof, whether or not a particular advantage is achieved by a given embodiment is not limited by this disclosure. The following aspects, features, embodiments, and advantages provided are merely illustrative; the aspects, features, embodiments, and advantages are not considered elements or limitations of the appended claims except where explicitly recited in one or more of the Claims. Likewise, one of skill in the art should not construe a reference to “the disclosure” as a generalization of any disclosed subject matter and shall not be considered an element or limitation of the appended claims except where explicitly recited in one or more of the Claims.

When patterning a design or placing an integrated module on a substrate, each substrate may be subject to conditions that may cause misplacement, mis-sizing, or other dispositioning that changes the configuration of the actual integrated module and the design to be patterned. Conventionally, changes to non-circuit-related structures were not of major concern. However, due to the ever-reduction in size of the circuitry, the increase in circuit density, and the multiple layers of circuitry, every position of every layer of an integrated circuit may have a structural impact upon the structure of the circuitry around the position but also upon the layers above and below the position. That is, the three-dimensional (3D) architecture of the chip group configuration should properly account for all layers. With increasing node density, increasingly localized and precise corrections are needed that can exceed the ability of a limited number of correction masks to correct.

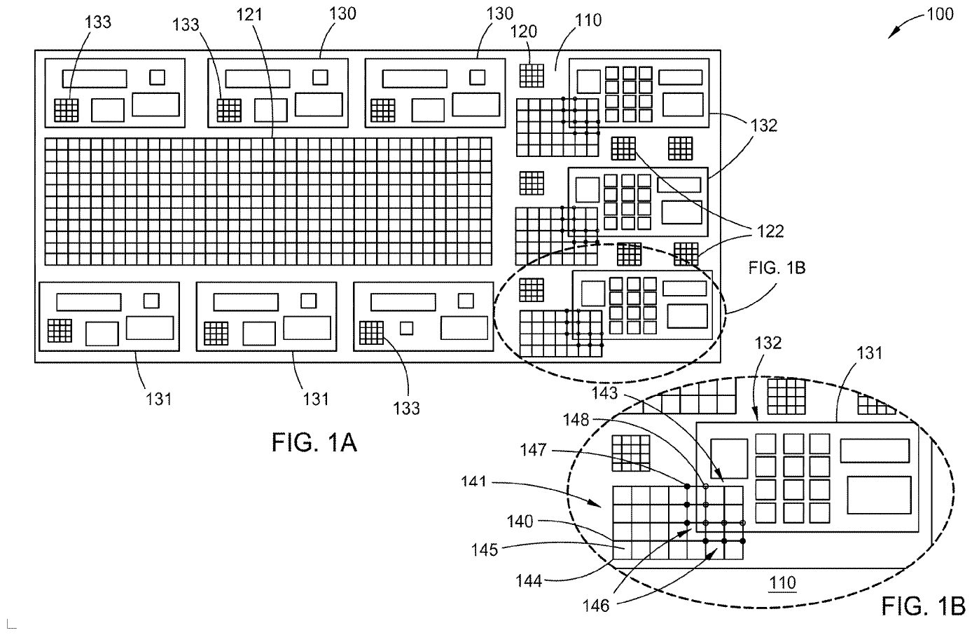

FIGS. 1A-1B may assist in elucidating the problem in a more appreciable context. FIG. 1A depicts a substrate layout design and FIG. 1B depicts a focused view enhancement of a portion of the substrate layout design. FIG. 1A shows a substrate layout design 100 with several chip groups and dummy fills (e.g. supplemental fills) on a substrate. In this context, a layout design may be a layout of design elements to be patterned on substrate 110, developed by a designer, programmatically, or a combination of both. Although the depicted example design shows a single layer, one of skill in the art will appreciated that a typical substrate design may include more than one layer for patterning on the substrate 110. Substrate layout design 100 is patterned on the substrate 110 and may include a variety of design elements limited only by the design required to meet one or more customer requirements. Such design elements may include, but are not limited to, connection lines, logic lines, transistors, vias to and from other layers, and several configurations of dummy fill 120, 122, which may be positioned and designed based upon the overall substrate layout design 100.

Chip group packages 130 may be a pre-assembled/fabricated element that may be introduced onto and incorporated as part of the substrate 110 during manufacturing. In one or more embodiments, chip group package layout designs 130 may be fabricated separately on substrate 110 from other design elements, such as other chip group packages and dummy fill. In one or more embodiments, chip group package layout designs 130 may include functional elements that provide functionality as part of the substrate layout design 100. In one or more embodiments, chip group package layout designs 130 and may include functional elements, including, but not limited to, memories, processors, application specific logic, lens arrays, active quantum dots, color filters, light focusing sidewall mirrors, and other components for additional functionality, or a combination thereof. As provided in one or more embodiments, such as in example substrate layout design 100, chip group package layout designs 130 includes collections of one or more chip-groups, such as first chip group packages 131 and second chip group packages 132.

There may be several areas on the substrate layout design in between and among the various chip group packages that may be utilized to fill and provide support for coatings and additional layers; therefore, underlying dummy fill is preferred to even out the surface. For example, substrate dummy fill 121 is shown as a large grid of open squares between several chip group package layout designs 130. Smaller grid formations of substrate dummy fill 121 appears positioned in spaces on the substrate 110 that would be between and among the second chip group packages 131. Dummy fill may not only be on the substrate surface but also on the chip group, although likely of thinner or more-shallow design. For example, chip-group dummy fill 133 is shown within the bounds of second chip group package 131. The substrate dummy fill 121 and/or the chip-group dummy fill 133 may be a repeating pattern across the substrate 110 or the chip-group. The substrate dummy fill 121 and the chip-group dummy fill 133 are independent of the connection elements of the layout design, e.g., the dummy fill substrate dummy fill 121 and the chip-group dummy fill 133 are not utilized to provide electrical connections throughout the layout design.

As can be seen in both FIGS. 1A and 1B, there is also a crossover dummy fill 140 such that there is a substrate portion 141, a chip group (CG) package portion 143, and a portion that crosses over the substrate/chip group boundary 132. Each dummy fill is made of a dummy fill material, such as dummy fill line 144. The dummy fill lines may form shapes, such as the grid patterns shown in dummy fills 120, 122, 133, and 140. These patterns of dummy fill material may also define dummy fill voids, or areas where there is an omission of dummy fill material, such as dummy fill void 145.

The portion of dummy fill material that crosses over the substrate/chip-group boundary 132 is the dummy fill interconnection segment 146. In the instance shown in both FIGS. 1A and 1B, the dummy fill pixel interconnection segment 146 connect substrate dummy fill connection point 147 and CG package dummy fill connection point 148 such that crossover dummy fill 140 appears continuous and congruous across the substrate/chip-group boundary 132 and as a singular structure. The dummy fill interconnection segment between the substrate dummy fill connection points and the GC dummy fill connection points will be described in additional detail forthcoming.

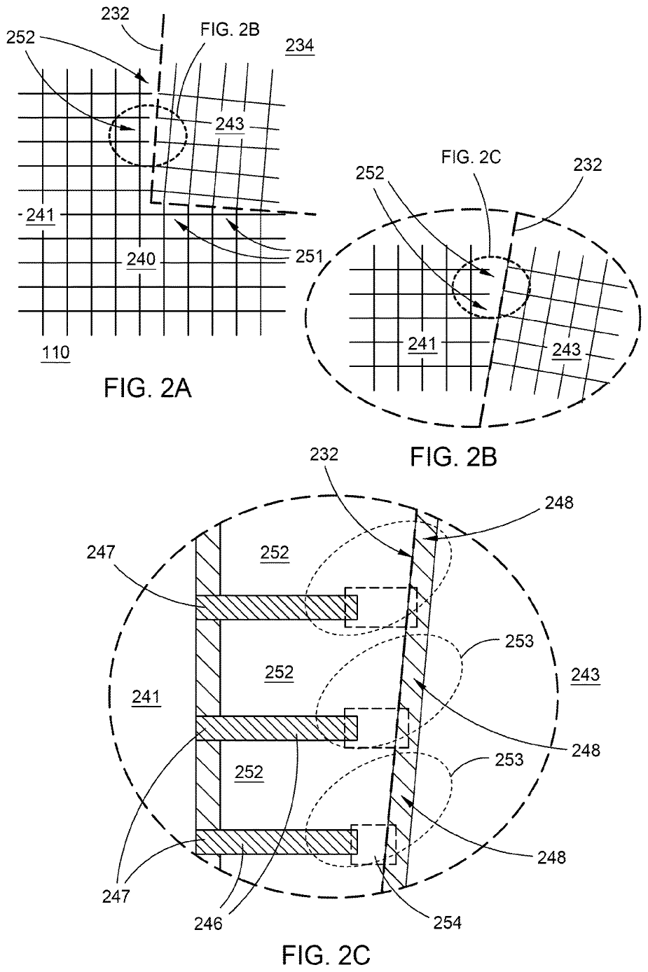

FIGS. 2A-2C show in greater detail several problems that may arise from misalignment of a chip group package on a substrate when a common dummy fill structure is involved. FIG. 2A depicts a focus view of a substrate layout design, and FIGS. 2B and 2C are enhanced focus views of the a substrate layout design of FIG. 2A showing potential defective features in a common dummy fill structure due to a misaligned chip group. Misaligned chip group package 234 has a substrate/chip group package boundary 232 (dashed line) that appears rotated relative to the grid pattern established the substrate portion 241 of the crossover dummy fill 240. This rotation appears to cause the CG portion 242 of the crossover dummy fill 240 to not be in a continuous grid-like alignment with the substrate portion 241.

Even at the view of FIG. 2A several problems can be readily seen. There are several smaller-than-expected dummy fill voids 251 and a large contiguous void 252 that have formed due to the misalignment. The smaller-than-expected dummy fill voids may be an issue because if the void is not a certain volume as defined by the dummy fill material configuration then the masking material may overflow or not even fill the void at all. Both may result in the mask material allotted to fill the dummy fill void overflowing into adjacent portions of the substrate layout design. As well, a large contiguous void would have the opposite problem-not enough masking material would be allocated for the increase in volume size, resulting in a depressed or uneven surface. This may detrimentally affect the layers that would be positioned above the continuous void if the change in layer height is not compensated for. FIG. 2B shows the large contiguous void 252 in greater detail.

FIGS. 2B and 2C visually introduces another problem caused by the misaligned chip group package: portions of the dummy fill are not connected across the substrate/chip group boundary. In FIG. 2C, due to the misalignment between the substrate portion 241 and the chip group package portion 243 the substrate dummy fill connection points 247 and the chip group package connection points 248 are not coupled together or overlapping. There may be sharp points or edges at the substrate dummy fill connection points that are not properly connected to associated CG dummy fill connection points. As well, a disjoinder 253 is shown between the connection points (long dash and 2 short dash ovals). These disjoinders 253 not only lead to formation of the contiguous void 252 previously described but also may create small areas of unfillable voids 254 (dotted rectangles) that are defined between the leading edge of the substrate dummy fill connection points 247 and the substrate/chip group package boundary 232. The variation between the areas of larger-than-normal voids (where there is too much volume to fill) and smaller than normal voids (where there is too little or no volume to fill) and exposure of possibly points or edges of fill material may cause the masking material to thin or even break and peel away near the area where the dummy fill connections should have been made if the alignment of the chip group package had been proper.

What is needed are systems and method to mitigate the shortcomings of prior approaches, if such approaches exist. Embodiments of the present disclosure therefore generally relate to systems, methods, and apparatuses regarding substrate processing of integrating pre-assembled components on a substrate. More particularly, the embodiment systems, methods, and apparatuses are associated with the detection and correction of misalignment of common-area dummy fill regions between chip groups (CGs) and the substrate. Such embodiments may also be useful for remedying misalignment within a regions of a chip group or a substrate.

Systems and methods disclosed generally related to masklessly exposed dummy fill connections between a chip group package dummy fill connection point on the chip group and a substrate design dummy fill connection point. In this context, a chip group is separately manufactured semiconductor product that is placed on a substrate or a design that is fabricated to the substrate by a separate process. In placement of the chip group package on the substrate, whether physically placed or separately fabricated, the chip group package may be misplaced, mis-sized, or otherwise dispositioned, relative to an expected position per a substrate layout design. In such an instance, this may cause a dummy fill connection misalignment with the design connection point for dummy fill on the substrate. According to one or more embodiments, a machine learning (ML) model is trained on historical and simulated pixel models of chip group package dummy fill connection points and substrate design dummy fill connection points. Upon determining the chip group package misalignment by a metrology measurement, the trained ML model determines a modified dummy fill pixel model interconnection to connect the misaligned chip group package dummy fill connection point and then causes a modified dummy fill pixel model connection line or connection segment to be exposed to a substrate, the chip group, or both, with a digital lithography tool. Upon exposure, the dispositioned chip group package dummy fill point and the design dummy fill connection point on the substrate are connected by a dummy fill segment or line that couples or connects the dummy fill configuration, making it continuous and contiguous.

Design needs for semiconductor devices such as integrated circuits, video displays, and other devices increasingly require separately fabricated components such as memories, processors, application specific logic, lens arrays, active quantum dots, color filters, light focusing sidewall mirrors, and other components for additional functionality. As these needs increase, the space on a given substrate to place these components requires ever-increasing precision of placement as available substrate space for corrections shrinks. Because of this, even the slightest misalignment of the dummy filler may impact the same or upper layer(s) of the device configuration.

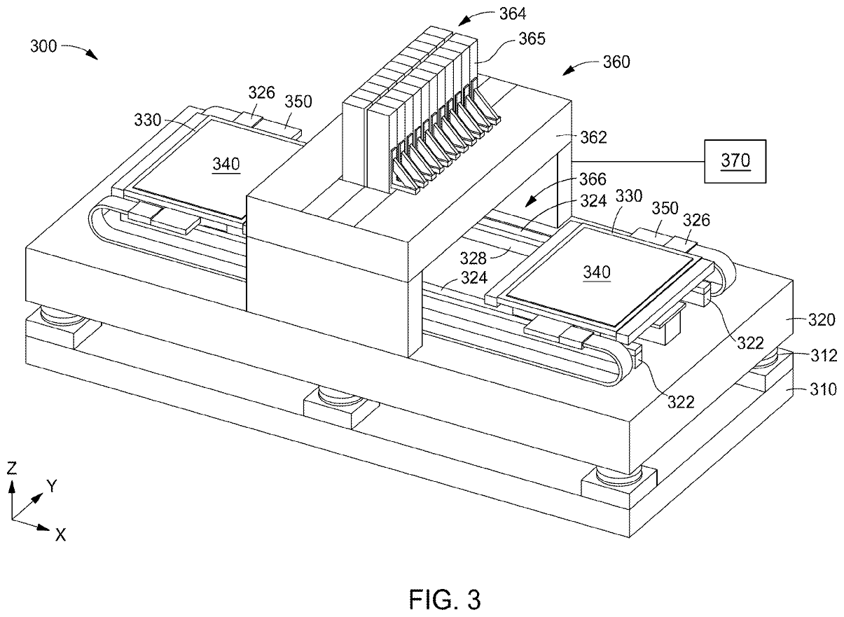

FIG. 3 depicts a perspective view of a system, according to one or more embodiments. FIG. 3 includes a system 300 that is a digital lithography tool that includes a base frame 310, a slab 320, a stage 330, and a processing apparatus 360. The base frame 310 rests on the floor of a fabrication facility and may support the slab 320. Passive air isolators 312 are positioned between the base frame 310 and the slab 320. The slab 320 may be a monolithic piece of granite, and the stage 330 is disposed on the slab 320. A substrate 340 may be supported by the stage 330. A plurality of holes (not shown) may be formed in the stage 330 for allowing a plurality of lift pins (not shown) to extend therethrough. The lift pins may rise to an extended position to receive the substrate 340, such as from a transfer robot (not shown). The transfer robot positions the substrate 340 on the lift pins, and the lift pins thereafter gently lower the substrate 340 onto the stage 330.

The substrate 340 may, for example, be made of quartz and be used as part of a flat panel display, and processes utilizing substrates made of different materials (for example, silicon, germanium, and combinations of materials) for different purposes (for example, integrated circuits (IC), application specific IC (ASIC)) may benefit from the disclosure. In one or more embodiments, the substrate 340 may be made of other materials. In one or more embodiments, a photoresist layer may be formed on the substrate 340. A photoresist is sensitive to radiation and may be a positive photoresist or a negative photoresist, meaning that portions of the photoresist exposed to radiation will be respectively soluble or insoluble to photoresist developer applied to the photoresist after the pattern is written into the photoresist. The chemical composition of the photoresist determines whether the photoresist will be a positive photoresist or negative photoresist. For example, the photoresist may include one or more of diazonaphthoquinone, a phenol formaldehyde resin, poly(methyl methacrylate) (PMMA), poly(methyl glutarimide), and SU-8, which is an epoxy-based negative photoresist. In this manner, the pattern may be created on a surface of the substrate 340 to form the electronic circuitry.

The system 300 further includes a pair of supports 322 and a pair of tracks 324. The pair of supports 322 are disposed on the slab 320, and the slab 320 and the pair of supports 322 may be a single piece of material. The pair of tracks 324 are supported by the pair of the supports 322, and the stage 330 moves along the tracks 324 in the in-scan direction. In one embodiment, the pair of tracks 324 is a pair of parallel magnetic channels. As shown, each track 324 of the pair of tracks 324 is linear. In other embodiments, the track 324 may have a non-linear shape. An encoder 326 or other sensor is coupled to the stage 330 in order to provide location information to a controller 370, and may detect movement in a stage due to vibration. In one or more embodiments, encoder 326 may be an interferometer or other device or sensor capable of detecting the location of a stage, vibration of a stage, and in-scan or cross-scan deviation of a stage due to vibration.

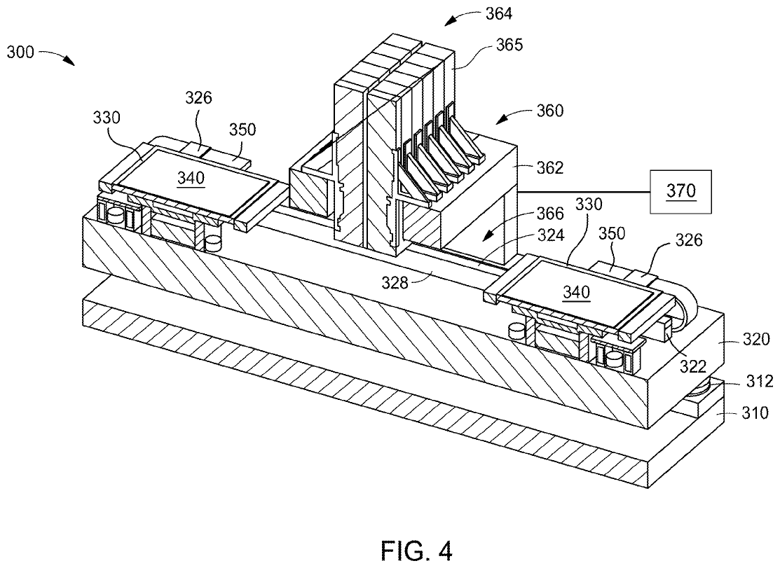

The processing apparatus 360 includes a support 362 and a processing unit 364. The support 362 is disposed on the slab 320 and may include an opening 366 for the stage 330 to pass under the processing unit 364. The processing unit 364 may be supported by the support 362. In one or more embodiments, the processing unit 364 is a pattern generator configured to expose a photoresist in a photolithography process. In some embodiments, the pattern generator may be configured to perform a maskless lithography process. The processing unit 364 may include a plurality of image projection systems (not shown) disposed in a case 365. The processing apparatus 360 may be utilized to perform maskless direct patterning. During operation, one of the stage 330 moves in the in-scan direction from a loading position, as shown in FIG. 3, to a processing position. The processing position may refer to one or more positions of the stage 330 as the stage 330 passes under the processing unit 364. During operation, the stage 330 is lifted by a plurality of air bearings 402 (shown in FIG. 4) and moves along the pair of tracks 324 from the loading position to the processing position. A plurality of vertical guide air bearings 402 (shown in FIG. 4) are coupled to the stage 330 and positioned adjacent an inner wall 328 of each support 322 in order to stabilize the movement of the stage 330. The stage 330 may also move in the cross-scan direction by moving along a track 350 for processing or indexing the substrate 340.

FIG. 4 is a cross-sectional side view of the system 300 of FIG. 3. As shown in the cross-sectional side view, the stage 330 includes a plurality of air bearings 402 for lifting the stage 330. Stage 330 may also include a motor coil (not shown) for moving the stage 330 along the tracks 324. The stage 330 and the processing apparatus 360 may be enclosed by an enclosure (not shown) in order to provide temperature and pressure control.

The system 300 also includes a controller 370. The controller is generally designed to facilitate the control and automation of the processing techniques described herein. The controller is coupled to or in communication with one or more of the processing apparatus 360, the stage 330, and the encoder 326. The processing apparatus 360 and the stage 330 provide information to the controller regarding the substrate processing and the substrate aligning. For example, the processing apparatus 360 may provide information to the controller to alert the controller that substrate processing has been completed. The encoder 326 may provide location information to the controller, and the location information is then used to control the stage 330 and the processing apparatus 360.

The controller may include a central processing unit (CPU) (not shown), memory (not shown), and support circuits (or I/O) (not shown). The CPU may be one of any form of computer processors that are used in industrial settings for controlling various processes and hardware (for example, pattern generators, motors) and monitor the processes (for example, processing time, substrate position). The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the controller determines which tasks are performable on a substrate. The program may be software readable by the controller and may include code to monitor and control, for example, the processing time and substrate position.

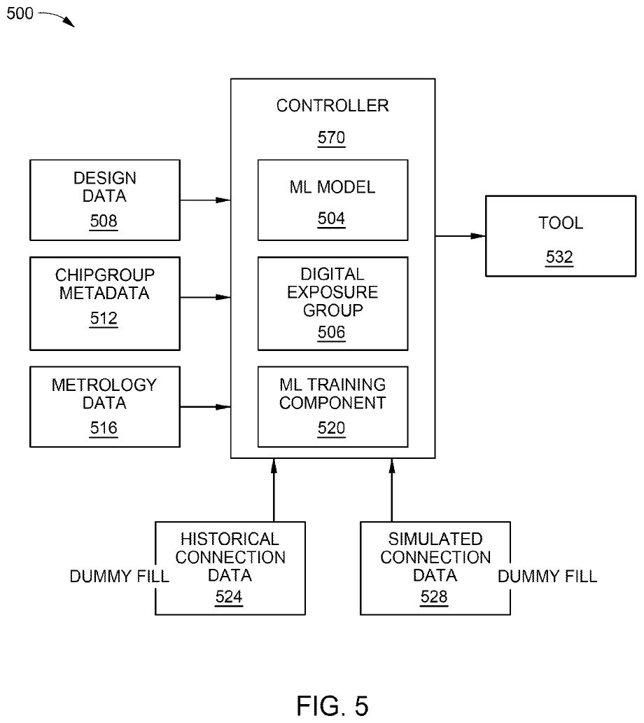

FIG. 5 depicts a schematic diagram 500 of a control system 570, which may be in some instances similar to the controller 370 as described associated with system 300 of FIGS. 3 and 4. Although the controller in this instances may be described as a unitary item, one or more embodiment controllers may comprise a single integrated circuit configured to perform functions, including one or more embodiment processes and methods to be described, a processor coupled to one or more memories, a standalone computing system, a group of computing systems coupled together utilizing wired or wireless connectivity, a distributed computing system, or a combination thereof.

Referring back to FIGS. 1A and 1B, substrate dummy fill connection point 147 and CG package dummy fill connection point 148 may be may be positioned to be connected via dummy fill pixel interconnection segment 146. Although shown as a points in FIGS. 1A and 1B, either or both substrate dummy fill connection point 147 and CG package dummy fill connection point 148 may comprise a point for connecting or coupling to dummy fill, a line extending from a point or an intersection of dummy fill, an intersection of two or more lines or curves of dummy fill, or an intermediary point along a line or curve of dummy fill, depending on the determination(s) made through the one or more embodiment methods, embodiments of which will be described forthcoming.

In addition to including functions for controlling and operating the digital lithography tool of systems 300, controller 570 of FIG. 5 may include a machine learning (ML) model 504. When a chip group layout package design, such as chip group layout package design 130 of FIGS. 1A and 1B, is patterned on a substrate, such as substrate 110, according to one or more embodiments the chip group package, such as chip group package 131 or 132, may be dispositioned, such as misaligned chip group package 234 of FIGS. 2A-2C. As a result, misconnected dummy fill interconnection segments 246 of FIG. 2C between the substrate dummy fill connection points 247 of the substrate layout design 100 and the CG dummy fill connection points 248 of the chip group package layout designs 130. If misconnected dummy fill interconnection segments 246 are patterned onto either the substrate 110 or the chip group 131, a proper dummy fill connection or coupling may not be formed between one or more substrate dummy fill connection points 247 and CG package dummy fill connection points 248, causing current and upper layer issues as previously described. According to one or more embodiment methods, metrology data for the dispositioned chip group package is determined by detecting the substrate 110 using a metrology tool 532, such as a scanner, through modeling of the chip group package.

According to one or more embodiments, the ML model takes the substrate layout design, the chip group layout package design, the metrology data (that is, the detected placement of the chip group package on the substrate), and the dummy fill pixel model interconnection, and determines a modified dummy fill pixel model interconnection for patterning on the substrate, the chip group, or both, so as to make one or more as modified dummy fill interconnections across the substrate/chip group boundary to create a continuous and contiguous dummy fill structure useful for supporting the current and upper layers of the board structure.

According to one or more embodiments, the modified dummy fill pixel model interconnection is provided to the system for optical imaging of the modified dummy fill pixel model interconnection onto the substrate. According to one or more embodiments, ML model is a component of a larger computer system, algorithm, or process for generating a modified dummy fill pixel model interconnection. In such embodiments, none, one, some, or all of the modified dummy fill pixel model interconnection generated by ML model is utilized to modify the substrate or chip group package.

In one or more embodiments, a pre-determined dummy fill pixel model interconnection is selected by a table lookup function residing in memory based on known disposition (for example, a known offset or rotation of the chip group package) as between a detected position substrate and detected chip group package components position to modify the dummy fill pixel model interconnection. In such embodiments, the table lookup determines a pre-determined dummy fill pixel model interconnection to select from a library of one or more pre-determined dummy fill pixel model interconnections configured to address hypothetical, known, or previously-addressed offsets between design elements. In one or more embodiments, a selected pre-determined dummy fill pixel model interconnection is then modified by the ML model to determine a modified dummy fill pixel model interconnection to utilize for a substrate/chip group package. Such look-up tables of hypothetical, known, or previously-addressed offsets, which may be based upon another determination using reference points on the substrate, the chip group package, or both, may save processing power and speed up a final determination of a modified dummy fill pixel model interconnection for application. In one or more embodiments where the correction needed is known, this data is provided to the ML model for the determination of the modified dummy fill pixel model interconnection. Alternatively, a modified dummy fill pixel model interconnection determined by the ML model is further modified based on the known disposition offset.

Because the modified dummy fill pixel model interconnection provides an affirmative and true dummy fill coupling or connection path between a chip group package and a substrate design to address a specific chip group package dispositioning, an advantage of this methodology is that no additional correction is needed. For example, a collection of correction masks is not needed for patterning modified dummy fill interconnections because the modified dummy fill pixel model interconnection is custom generated for each particular dispositioning and connection pair.

Although the one or more embodiments described contemplate generating a modified dummy fill pixel model interconnection for coupling or connecting the portion of the dummy fill on a dispositioned chip group package to the portion of the dummy fill on a substrate across the substrate/chip group package boundary, one of skill in the art will appreciate that other types of dispositioning may be addressed according to one or more embodiments. For example, if two design connection points on a substrate are not patterned as defined by a substrate design layout due to non-design factors, including, but not limited to, vibration, humidity, particle contamination, and SLM (silicon lifecycle management) skew, the methods and processes techniques described may be beneficially employed to develop modified dummy fill pixel model interconnections that addresses such dispositioning. Moreover, relative dispositioning between and within chip groups may be addressed by such methods and processes as described.

According to one or more embodiments, the ML model, such as ML model 504, may be a supervised or unsupervised machine learning model. According to one or more embodiments, ML model is a classifier, such as a neural network, a deep learning neural network, k-means classifier, random forest walk, or a similar neural network learning machine, configured to receive an input, for example, metrology data of an actual substrate, such as substrate 110, processed by a digital lithography tool, such as a system 300, and determine a dispositioning between components on the substrate versus a substrate layout design, such as substrate layout design 100. By way of example and not limitation, ML model may receive as inputs substrate layout design, detected metrology data, including detected data regarding one or more dispositioned elements on a substrate versus the substrate layout design, and a dummy fill interconnection segment, such as dummy fill interconnection segment 146, for making the coupling or connection between a substrate element to a chip group package element of the substrate layout design when not dispositioned, to determine the degree of dispositioning and, as a result of the determine of degree of dispositioning, determined a modified dummy fill pixel model interconnection segment to address the dispositioning (for example, generate a modified dummy fill pixel interconnection segment or line to couple using dummy fill material the dispositioned element to the substrate element).

A controller, such as controller 370, of a digital lithography tool, such as system 300, receives design data, such as design data 508 that includes, but it is not limited to, substrate layout design data, such as substrate layout design 100, and chip group package layout design data, such as chip group package layout design 130, to determine a digital exposure group 506. Digital exposure group includes the digital exposure group data for making modifications to untreated substrate. Design data 508 in some instances may include or be accompanied separately by chip group metadata 512 to introduce or modify the digital exposure group data. Chip group package metadata 512 may include information about the placements of the chip group design cell instances on the substrate layout design and the dummy fill couplings, connections, or connection segments that are to be transformed with the ML model.

ML model 504 may also receive and utilize metrology data 516 generated by a metrology tool (not shown) to generate a digital exposure group 506. The metrology tool detects the metrology of the substrate, such as substrate 110, by measuring the patterned dummy fills 121, 133, and 140, using the substrate layout design 100, the chip group package layout design 130, or both, or generated by simulating this metrology. In one or more embodiments, the metrology data 516 may also contain determined differences between the respective substrate layout and chip group package layout and the measured dummy fill patterns.

Digital exposure group 506 may then be introduced to a tool, such as tool 532, that is connected, coupled, or in communication with a digital lithography tool, such as that of system 300, for pattering the modified dummy fill pixel model interconnection onto the substrate, such as substrate 110, the chip group package, such as chip group package 234, or both, in one or more embodiments.

A controller comprising a ML model in one or more embodiments further includes ML training component for training the ML model. ML training component, such as ML training component 520, may receive historical connection data, such as historical dummy fill connection data 524, simulated connection data, such as simulated dummy fill connection data 528, or both, to train ML model 504. Historical dummy fill connection data 524 and simulated dummy fill connection data 528 in this context may be pixel models of dummy fill interconnections between chip group package dummy fill connection points and substrate dummy fill connection points, connections between two (or more) substrate dummy fill connection points, or connections between two (or more) chip group package dummy fill connection points, in which one or both connection points were dispositioned. For historical data, historical dummy fill connection data 524 may comprise historical dummy fill pixel model interconnection data from previously measured patterned substrates (for example, metrology data) that are indicated as dispositioned. Simulated dummy fill connection data 528 may include simulated pixel model data, such as paths between connection points that are simulated as dispositioned.

According to one or more embodiments, ML model may be trained offline or at a time before a process utilizing the digital lithography tool is undertaken. In one or more embodiments, training of the ML model may occur as the digital lithography tool is processing a substrate. Once trained, ML model 504 may receive data as previously described to determine the modified dummy fill pixel model interconnection to the tool that patterns dummy fill, such as a pattering tool associated with the digital lithography tool.

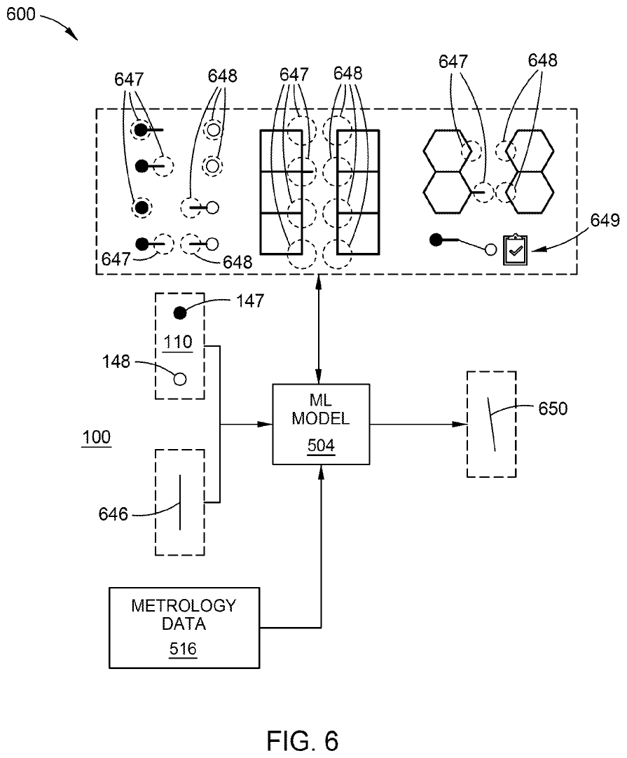

FIG. 6 depicts a schematic diagram 600 for a machine learning (ML) model, such as ML model 504. In training the ML training component, such as ML training component 520, various model combinations 650 of training substrate dummy fill connection points 647 and training CG package dummy fill connection points 648, including variations of dummy fill points, dummy fill line segments, and geometric pattern intersections as part of larger patterns of dummy fill across the substrate/chip group package boundary, may be provided to enhance recognition by the ML model 504 connection locations, association of combinations of coupling or connection locations, and in some instances generate alternative combinations of coupling or connection locations based upon one or more preset rules about a dummy fill structure across a substrate/chip group package boundary. In some other instance, the ML training component may well also provide examples of previously-determined or verified coupling or connection dummy fill interconnection segments, such as verified dummy fill interconnections 649, for use in establishing potential interconnections. In one or more embodiments, the ML training component 520 may re-access the various model combinations 650 based upon pre-set training rules, such as detecting a greater-than-significant amount of a particular detected variation or combination. Inn such instances, the ML mole 504 may continue to train autonomously offline or during production activities based upon continued detections and determinations.

After training by ML training component 520, ML model 504 may detect both a substrate dummy fill connection point, such as substrate dummy fill connection point 147, an associated CG package dummy fill connection point, such as CG package dummy fill connection point 148, on a substrate 110. In one or more embodiments, the ML model may also detect the alignment of the chip group package boundary relative to other geometric point on the substrate. The ML model 504 may also receive a dummy fill pixel model interconnection segment 646 that is configured for use with the substrate layout design, such as substrate layout design 100, to couple or connect the associated substrate dummy fill connection and the CG package dummy fill connection points. The ML model 504 may also determine an offset (for example, misplacement, rotation, mis-sizing, and combinations thereof) between substrate dummy fill connection point and associated CG package dummy fill connection point as patterned on the substrate utilizing metrology data 516. ML model 504, utilizing the received designs and data, converts the dummy fill pixel model interconnection segment, such as dummy fill pixel model interconnection segment 646, into a modified dummy fill pixel model interconnection segment, such as modified dummy fill pixel model interconnection segment 650.

This conversion of the original dummy fill pixel model interconnection segment associated with the substrate layout design to one that is configured for the actual substrate configuration is then provided to the system controller, such as controller 370 of FIGS. 3 and 4. In such instances, the controller then directs the digital lithography tool, such as those systems 300 of FIGS. 3 and 4, respectively, to pattern onto the substrate, such as substrate 110, the modified dummy fill pixel model interconnection segment as dummy fill interconnection segment, such as dummy fill interconnection segment 146 to couple or connect associated substrate dummy fill connection and CG package dummy fill connection points. Such operations will be described in more detail forthcoming.

In the aforementioned embodiment process described, a geometric definition of the couplings or connections are first determined as pixel models and then modified. In one or more embodiments, a connection pixel model may also be generated during the process from corresponding chip group package metadata.

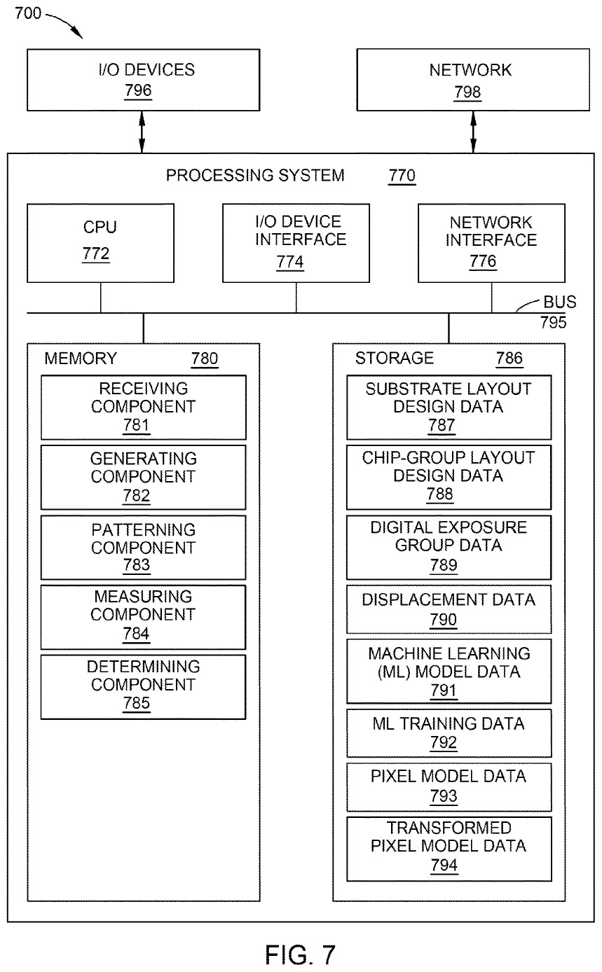

FIG. 7 depicts a block diagram of an embodiment computer system. Embodiment computer system 700 may be utilized to provide computational functionalities associated with one or more embodiment described algorithms, methods, functions, processes, flows, and procedures as described in this disclosure. Embodiment computer system 700 may include a processing system 770. Processing system 770 may be an example of a controller, such as controller 370, according to one or more embodiments. In one or more embodiments of a system, processing system may be used in place of a controller as previously described. An embodiment processing system may be configured to operate one or more embodiments systems as previously described to perform one or more operations of one or more embodiment methods and processes as described and to be described, such as correcting locally dispositioned dummy fill patterns by dynamic digital correction.

The processing system 770 is intended to encompass any computing device, such as a server, a desktop computer, a laptop/notebook computer, a wireless data port, a smart phone, a personal data assistant (PDA), a tablet computing device, or one or more processors within these devices, including physical instances, virtual instances, or both. One or more embodiment processing system may include input devices such as keypads, keyboards, and touch screens that can accept user information. One or more embodiment processing systems may include output devices that can convey information associated with the operation of the processing system. Such information may include digital data, visual data, audio information, or a combination of information. The information can be presented in a graphical user interface (UI) (or GUI).

One or more embodiment processing systems may serve in a role as a client, a network component, a server, a database, a persistency, or components of a computer system for performing the subject matter described in this disclosure. The illustrated processing system 770 in FIG. 7 is communicably coupled with a network 798. In one or more embodiments, one or more components of the processing system may be configured to operate within different environments, including cloud-computing-based environments, local environments, global environments, and combinations of environments.

At a high level, the one or more embodiment processing systems is an electronic computing device operable to receive, transmit, process, store, and manage data and information associated with the described subject matter. According to some one or more embodiments, the processing system man also include, or be communicably coupled with, an application server, an email server, a web server, a caching server, a streaming data server, or a combination of servers.

The one or more embodiment processing systems may receive requests over network 798 from a client application (for example, a program executing on another computer). The processing system may respond to the received requests by processing the received requests using one or more software applications. Requests can also be sent to the embodiment processing system from internal users (for example, from a command console), external (or third) parties, automated applications, entities, individuals, systems, and computers.

Processing system 770 may include a central processing unit (CPU) 772. In one or more embodiments, the CPU 772 is configured to process computer-executable instructions that are stored in memory 780 or are retrieved from storage 786 into memory 780. Processing of computer-executable instructions causes the computer system 700 to perform or transmit instruction to other devices to perform using algorithms, methods, functions, processes, flows, or procedures one or more steps of the one or more embodiment methods and processes described. Instances of the CPU may include a single CPU, multiple CPUs, a single CPU having multiple processing cores, and other forms of processing architecture configured to execute computer-executable instructions.

Each of the components of the processing system 770 may communicate using a system bus 795. In one or more embodiments, any or all of the components of the processing system 770, including hardware or software components, may interface with each other or the I/O interface 774 (or a combination of both) utilizing the system bus 795.

Computer system 700 may include input/output (I/O) device(s) 796 coupled to processing system 770 in one or more embodiments. In such embodiments, the processing system 770 may include I/O interface 774. Although illustrated as a single interface, two or more interfaces may be used according to particular needs, desires, or particular implementations of the processing system 770 and the described functionality. The I/O interface 774may allow processing system 770 to communicate with one or more input/output devices 796, such as keyboards, displays, mouse devices, pen input, and other devices that are configured for interpreting human or other computer interaction to or from processing system 770. Note that processing system 1300 may connect with external I/O devices, for example, an external display device, through either or both physical or non-physical (that is, wireless) couplings or connections.

Processing system 770 in one or more embodiments may further include a network interface 776. Network interface may be used by the processing system for communicating with other systems that are connected to the network (whether illustrated or not) in a distributed environment. Generally, the network interface may include, or be implemented using, logic encoded in software or hardware (or a combination of software and hardware) operable to communicate with the network. More specifically, the network interface may include software supporting one or more communication protocols associated with communications. As such, the network or the hardware for the network interface may be configured to communicate physical signals within and outside of the illustrated computer system 700.

In one or more embodiments, the interfaces of the processing system, such as processing system 770, may use an application programming interface (API), a service layer, or a combination thereof. The API may include specifications for routines, data structures, and object classes. The API may be either computer-language independent or dependent. The API may refer to a complete interface, a single function, or a set of APIs.

The service layer may provide software services to the processing system 770 and other components (whether illustrated or not) that are communicably coupled to the processing system 770. The functionality of the processing system 770 may be accessible for all service consumers using this service layer. Software services, such as those provided by the service layer, may provide reusable, defined functionalities through a defined interface. For example, the interface may be software written in JAVA, C++, or a language providing data in extensible markup language (XML) format. While illustrated as an integrated component of the processing system 770, in alternative implementations, the API or the service layer may be stand-alone components in relation to other components of the processing system 770 and other components communicably coupled to the processing system 770. Moreover, any or all parts of the API or the service layer may be implemented as child or sub-modules of another software module, enterprise application, or hardware module without departing from the scope of the present disclosure.

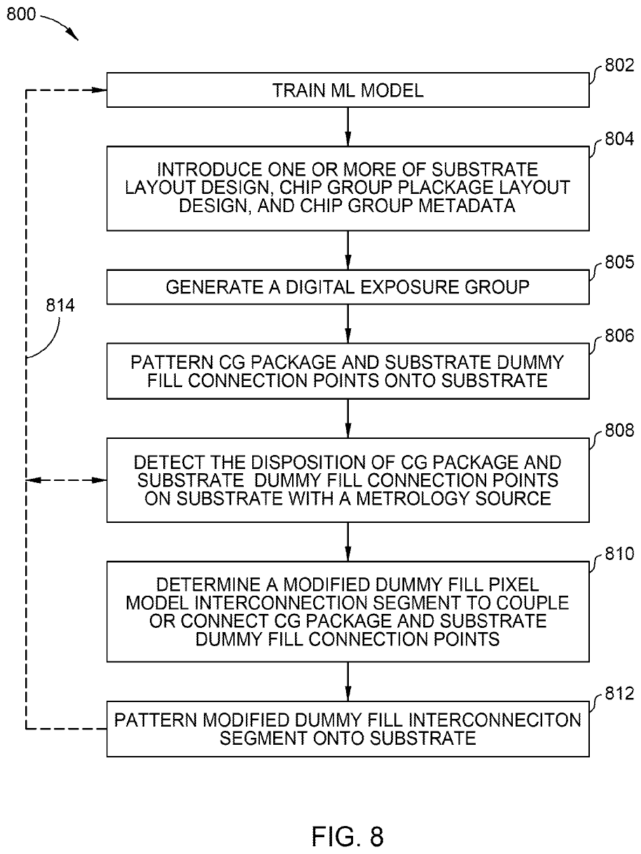

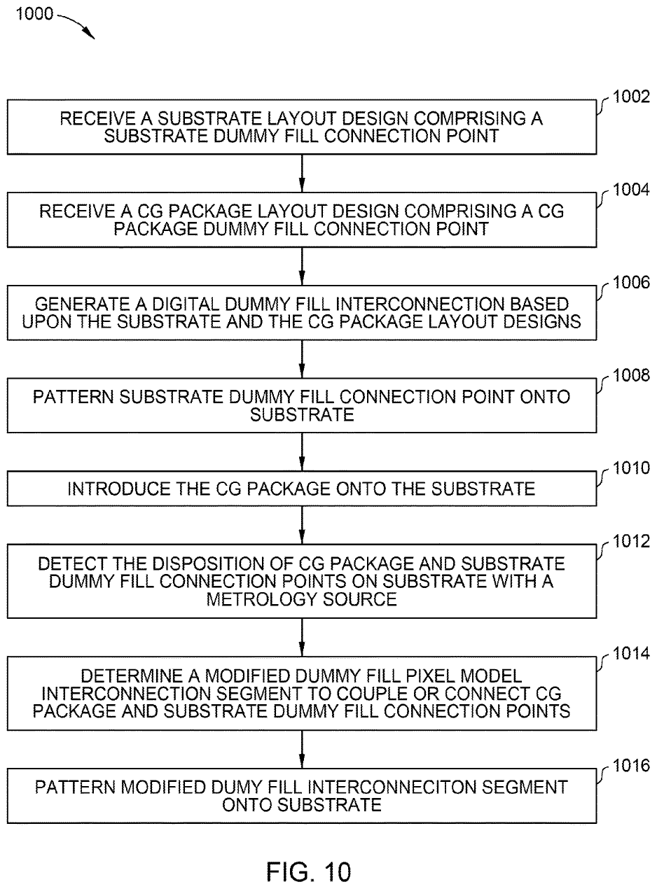

In one or more embodiments, the processing system 770 further includes memory 780. Residing actively within memory 780 may include, but is not limited to, functional components and applications for performing the aforementioned and to be describe one or more embodiment methods and process. Examples of such functional components include as a receiving component 781, generating component 782, patterning component 783, detecting component 784, and determining component 781 for performing operations described, for example, in connection with methods and processes provided for in FIGS. 8 and 10.

Applications may be an algorithmic software engine providing functionality according to particular needs, desires, or particular implementations of the processing system and the described functionality. For example, an application may serve as one or more components, modules, or applications. Further, an application may be implemented as a single or multiple applications on the processing system. The application may operate internal to the computer, external to the computer, or a combination thereof.

Note that while shown as a single memory 780 in FIG. 7 for the sake of simplicity, the various function and applications accessible in memory may be stored in different physical memories, including memories remote from processing system but accessible by CPU via internal data connections, such as bus, or via external data connections, such as network interface or I/O device interface. Two or more memories (of the same, different, or combination of types) may be used according to particular needs, desires, or particular implementations of the processing system and the described functionality.

Storage 786 further includes substrate layout design data 787, CG package layout design data 788, digital exposure group data 789, displacement data 790, machine learning (ML) dynamic digital corrections model data 791, ML training data 792, dummy fill pixel model interconnection segment data 793, and modified dummy fill pixel model interconnection segment data 794, for performing operations described. As would be appreciated by one of ordinary skill, other data and aspects may be included in physical storage.

Note that while shown as a single storage in FIG. 7 for the sake of simplicity, the various function and applications accessible in storage 786 may be stored in different physical storages, including storages remote from processing system but accessible by CPU via internal data connections, such as bus, or via external data connections, such as network interface or I/O device interface. Two or more storages (of the same, different, or combination of types) may be used according to particular needs, desires, or particular implementations of the processing system and the described functionality.

The storage may also include a database structure or format that may hold data for the process system 770 and other components connected to the network 798 (whether illustrated or not). For example, a database may be an in-memory, conventional, or a database storing data consistent with the present disclosure. In one or more embodiments, a database be a combination of two or more different database types (for example, hybrid in-memory and conventional databases) according to particular needs, desires, or particular implementations of the process system and the described functionality. A single or a plurality of databases (of the same, different, or combination of types) may be used according to particular needs, desires, or particular implementations of the process system and the described functionality.

The process system may also include a power supply. The power supply may include a rechargeable or non-rechargeable battery that may be configured to be either user-or non-user-replaceable. In one or more embodiments, the power supply may include power-conversion and management circuits, including recharging, standby, and power management functionalities. In one or more embodiments, the power supply may include a power plug to allow the process system to be plugged into a wall socket or a power source to, for example, power the process system to recharge a rechargeable battery.

There may be any number of process system associated with, or external to, a computer system 700 containing process system 770, with each process system communicating over network 798. Further, the terms “client,” “user,” and other appropriate terminology may be used interchangeably, as appropriate, without departing from the scope of the present disclosure. Moreover, the present disclosure contemplates that many users may use one process system and one user may use multiple process systems.

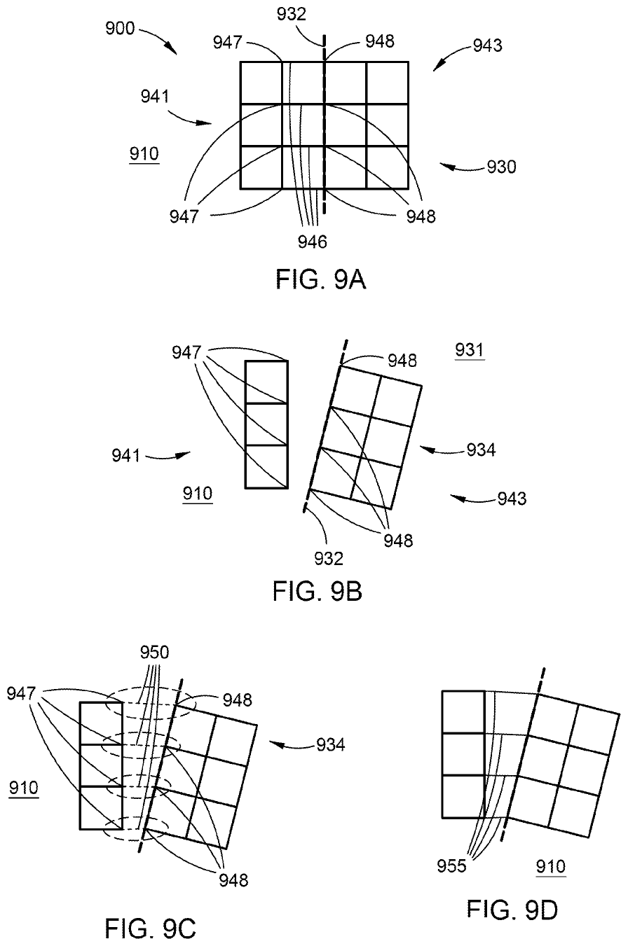

FIG. 8 depicts an embodiment flow diagram for correcting locally dispositioned dummy fill patterns by machine learning (ML)-based dynamic digital corrections. In describing the one or more operations in the method provided for in the flow diagram 800 for FIG. 8, FIGS. 9A-D may be useful in understanding and appreciating certain aspects of the method for correcting locally dispositioned dummy fill patterns by machine learning (ML)-based dynamic digital correction.

In one or more embodiments, at block 802 the ML-based dynamic digital corrections model may be trained by a ML training component, as previously described, by modifying the ML dynamic digital corrections model data with ML training data. The trained ML-based dynamic digital corrections model may reside in memory of a computer controller, such as controller 370 of a digital lithography tool, such as digital lithography tools of FIGS. 3 and 4, respectively.

In one or more embodiments, the ML-based dynamic digital corrections model may be configured to autonomously train itself to enhance ML-based dynamic digital corrections model's determination features by obtaining and incorporating new ML training data into its ML dynamic digital corrections model data based upon a given stimulus or event. An example of such “self-training” based upon production is introducing (814) the resultant determination of block 812 back to block 802 as part of the modification and continued enhancement of the model. In doing so, the ML training module of the ML-based dynamic digital correction model may retrieve the detected metrology data from block 808 associated with the modified dummy fill pixel model interconnection segments to correlate the data.

Optionally, in one or more embodiments the ML based dynamic digital corrections model may be provided as a pre-trained system by a third-party. In other instances, the ML-based dynamic digital corrections model may be utilized “as-is”, that is, no additional training occurs with the system after introduced into a production cycle.

In one or more embodiments, at block 804 one or more of substrate layout design, chip group package layout design data, and chip group metadata, may be introduced to the controller of the digital lithography tool. FIG. 9A depicts an embodiment of a portion of a substrate layout design 900. Substrate layout design 900 shows features of a configuration for a crossover dummy fill that includes a substrate portion 941 with substrate dummy fill connection points 947 identified and dummy fill interconnection segments 946 connected to them on one end of each segment. Substrate layout design 900 is also shown including a portion of a chip group package layout design 930 featuring CG portion 943 of the crossover dummy fill, the substrate/chip group package boundary 932, and CG dummy fill connection points 948 connected to the other end of the dummy fill interconnection segments 946. In such embodiments, digital exposure group data may include a layout of design elements to be patterned on the substrate, such as substrate 110. Such a digital layout design may be developed by a designer, programmatically, or a combination of both.

In one or more embodiments, at block 805 the controller of the system may utilize one or more of the layout design data and metadata to generate a digital exposure group. The data for the digital exposure group will be utilized to pattern the substrate.

In one or more embodiments, at block 806 the system patterns the chip group package and the substrate dummy fill connection points onto the substrate based upon the digital exposure group data. The system may also pattern various other elements and features based upon the one or more of substrate layout design, chip group package layout design data, and chip group metadata onto the substrate, such as what is featured in FIGS. 1A and 1B.

FIG. 9B depicts an embodiment of a potential result of patterning a substrate layout design on a substrate. In FIG. 9B, CG package 931, substrate portion 941 of the crossover dummy fill, substrate/CG boundary 932, and CG portion of the crossover dummy fill are etched into or applied onto the substrate 110 surface and are now detectable and recognizable. As may be seen visually in the drawing, although one of ordinary skill in the art appreciates that in some instances a misalignment in reference of one structure to another may not be directly visually observable, for FIG. 9B it appears that chip group package 931, such as misaligned chip group package 934, is misaligned with the configuration of the associated substrate dummy fill group pattern. This may be the genesis of many of the issues previously described with the structural relationships shown in FIGS. 2A-C unless there is an intervention before the dummy fill interconnection, such as patterning dummy fill interconnection segments 946, are made.

In one or more embodiments, at block 808 metrology data is detected for the patterned substrate 910 from a metrology source by detecting associated data from the substrate, such as by scanning substrate with a metrology tool, simulating metrology measurements, or both. FIG. 9C depicts the detection (dash-dash-dot ovals) of the degree of misalignment of the misaligned CG package 934 and its CG dummy fill connection points 948 in relation to each of their associated substrate dummy fill connection points 947. The detected degree of misalignment and the positions of the dummy fill connection points is converted into displacement data in the controller. If the dummy fill interconnection segments would have been applied at this time to the substrate between the unintentionally misaligned dummy fill connection points, the results would have been similar to what is shown in FIG. 2C.

In one or more embodiments, at block 810 the controller through the ML model determines a modified dummy fill pixel model interconnection segment to couple or connect the associated CG package and substrate dummy fill connection points. As previously described, the ML model, using the metrology sourced displacement data as well as accessing prior successful solutions in similar instances may derive a unique modified dummy fill pixel model interconnection segment 950 solution (dotted line) for each of the associated pairs of connection points 947, 948 (dash-dash-dot ovals) as shown in FIG. 9C. In one or more embodiments, the modified dummy fill pixel model interconnection segment may be derived from a combination of the dummy fill pixel model interconnection segment data in the digital exposure group data and the metrology sourced displacement data. In one or more embodiments, the modified dummy fill pixel model interconnection segment is derived solely using the metrology sourced displacement data.

In one or more embodiments, at block 812 the modified dummy fill pixel model interconnection segments determined in block 810 is patterned onto the substrate as modified dummy fill interconnection segments, such as segments 955 of FIG. 9D. FIG. 9D depicts an embodiment mitigated crossover dummy fill pattern with modified dummy fill interconnection segments. The patterning couples or connects the associated CG package and substrate dummy fill connection points. As one of skill may observe, the pattering of the modified dummy fill interconnection segments does not correct the misalignment of the misaligned chip group package; rather, it mitigates the misalignment by compensating for the misalignment and adapting the dummy fill pattern so that it remains continuous and contiguous. The segments 955 may be configured as a repeating pattern, such as a grid, to correspond to the repeating pattern of the substrate dummy fill 121 and/or the chip-group dummy fill 133 disposed over the substrate and the chip-group.

Although dispositioning is shown in this example as rotation, other types of displacement of the chip group package may utilize the techniques described to generate and then implement a dummy fill interconnection between a chip group connection point and a design connection point. Dispositioning in this context may, in addition to rotation, may include shifting laterally, longitudinally, or both, as well as mis-sizing. There might be also sizing change of the chip group package that can cause positional displacement of a connection point.

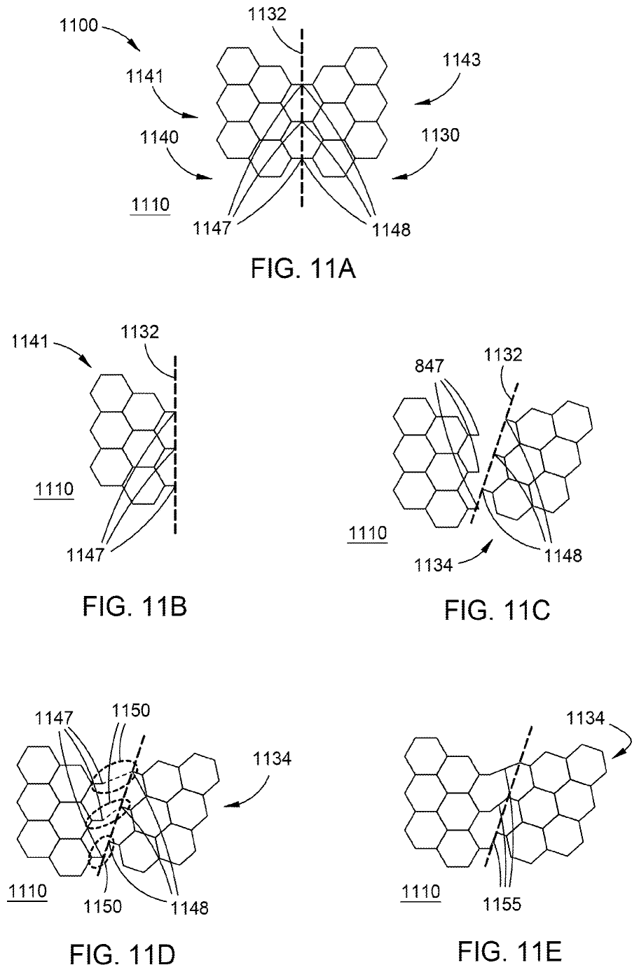

FIG. 10 depicts a second embodiment flow diagram for correcting locally dispositioned dummy fill patterns by machine learning (ML)-based dynamic digital corrections. In describing the one or more operations in the method provided for in the flow diagram 1000 for FIG. 10, FIGS. 11A-E may be useful in understanding and appreciating certain aspects of the method for correcting locally dispositioned dummy fill patterns by machine learning (ML)-based dynamic digital correction.

In one or more embodiments, at block 1002 a substrate layout design may be introduced to the controller of the digital lithography tool. The substrate layout design received may comprise a substrate dummy fill connection point. In one or more embodiments, at block 1004 a chip group package layout design data may be introduced to the controller of the digital lithography tool. The CG package layout design received may comprise a CG package dummy fill connection point. Both the substrate and the CG package dummy fill connection points may become part of the digital exposure group data utilized by the controller.

FIG. 11A depicts an embodiment of a portion of a substrate layout design 1100. Substrate layout design 1100, which is shown including features of a configuration for a crossover dummy fill 1140 that includes a substrate portion 1141 with substrate dummy fill connection points 1147 identified. Substrate layout design 1100 is also shown including a portion of a chip group package layout design 1130 featuring CG portion 1143 of the crossover dummy fill 1140, the substrate/chip group package boundary 1132, and CG dummy fill connection points 1148.

In one or more embodiments, at block 1006 a digital dummy fill interconnection based upon the substrate and the chip group package layout designs is generated within the controller, such as a processing system, by an application, such as a ML model residing in memory, and included in the digital exposure group utilizing the digital exposure data previously received.

In visualizing the digital exposure group data as part of FIG. 11A, in this instance there are no dummy fill interconnection segments to be generated based upon the design of the crossover dummy fill. Each substrate dummy fill connection point 1147 and the associated chip group dummy fill connection point 1148 are actually located at the same position along the substrate/chip group boundary 1132. In the manner in which the hexagonal pattern on each side of the substrate/chip group boundary 1132 is configured, a dedicated dummy fill interconnection segment should be unnecessary if there is no misalignment after chip group package introduction.

At block 1008, in one or more embodiments a dummy fill connection point is patterned onto the substrate. FIG. 11B depicts part of a potential result of patterning a substrate layout design on a substrate. In FIG. 11B, substrate portion 1141 in a hexagonal dummy fill pattern along with several partial hexagon side extensions leading to several substrate dummy fill connection points 1147 at the substrate/chip group boundary 1132 are patterned onto the surface of the substrate 1110.

At block 1010, in one or more embodiments the chip group package is introduced onto the substrate. FIG. 11C depicts a potential result of patterning a substrate layout design on a substrate. Although in most instances this occurs without incident that would detrimentally affect the configuration of the dummy fill, in the case of the introduction of the chip group package for FIG. 11C shows misaligned chip group package 1134 present. Chip group dummy fill connection points 1148 are not in the same position as substrate dummy fill connection points 1147; therefore, there is a break in the dummy fill pattern across the substrate/chip group boundary 1132 that may cause issues upon further processing.

Mitigation efforts to any misapplication of a chip group package may occur starting at block 1012. In one or more embodiments, at block 1012 metrology data is detected for the patterned substrate 1110 from a metrology source by detecting associated data from the substrate, such as by scanning the substrate with a metrology tool, simulating metrology measurements, or both. FIG. 11D depicts the detection of the degree of misalignment of the misaligned CG package and its CG dummy fill connection points in relation to each of their associated substrate dummy fill connection points. As seen in FIG. 11D, the misalignment causes the CG dummy fill connection points 1148 to separate from their associated substrate dummy fill connection points 1147. This separation is detected (dash-dash-dot ovals) and converted into displacement data. The measurement between each associated set of points is determined such that a model may be generated to mitigate each of the unique disconnections.

In one or more embodiments, at block 1014 the controller through the ML model determines a modified dummy fill pixel model interconnection segment to couple or connect each associated CG dummy fill connection point 1147 with the substrate connection point 1148. The ML model in this instance using the metrology sourced displacement data may derive a modified dummy fill pixel model interconnection segment 1150 solution (dotted line) for each of the associated pairs of connection points 1147, 1148 (dash-dash-dot ovals) as shown in FIG. 11D. Given that there was no previous dummy fill interconnection segment data to utilize because of the connection points overlap, each modified dummy fill pixel model interconnection segment is original and new-each did not previously exist.

FIG. 11E depicts an embodiment mitigated crossover dummy fill pattern with modified dummy fill interconnection segments. As shown in FIG. 11E, the hexagonal dummy fill pattern is repaired based upon the dummy fill connection point rules utilized by the ML model. In one or more embodiments, at block 1016 the modified dummy fill pixel model interconnection segments determined in block 1014 are introduced by pattering the modified dummy fill interconnection segments, such as segments 1155 of FIG. 11E, onto the substrate 1110. The patterning couples or connects the associated CG package and substrate dummy fill connection points. As one of skill may observe, the pattering of the modified dummy fill interconnection segments does not correct the misalignment of the misaligned chip group package; rather, it mitigates the misalignment by compensating for the misalignment and adapting the dummy fill pattern so that it remains continuous and contiguous.

Implementations of the subject matter and the functional operations described in this specification may be implemented in digital electronic circuitry, in tangibly embodied computer software or firmware, in computer hardware, including the structures disclosed in this specification and their structural equivalents, or in combinations of one or more of them. Software implementations of the described subject matter may be implemented as one or more computer programs. Each computer program may include one or more modules of computer program instructions encoded on a tangible, non-transitory, computer-readable computer-storage medium for execution by, or to control the operation of, data processing apparatus. Alternatively, or additionally, the program instructions may be encoded in/on an artificially generated propagated signal. For example, the signal may be a machine-generated electrical, optical, or electromagnetic signal that is generated to encode information for transmission to a suitable receiver apparatus for execution by a data processing apparatus. The computer-storage medium may be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus may encompass all kinds of apparatuses, devices, and machines for processing data, including by way of example, a programmable processor, a computer, or multiple processors or computers. The apparatus may also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) may be hardware-or software-based (or a combination of both hardware-and software-based). The apparatus may optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which may also be referred to or described as a program, software, a software application, a module, a software module, a script, or code, may be written in any form of programming language. Programming languages may include, for example, compiled languages, interpreted languages, declarative languages, or procedural languages. Programs may be deployed in any form, including as stand-alone programs, modules, components, subroutines, or units for use in a computing environment. A computer program may, but need not, correspond to a file in a file system. A program may be stored in a portion of a file that holds other programs or data, for example, one or more scripts stored in a markup language document, in a single file dedicated to the program in question, or in multiple coordinated files storing one or more modules, sub-programs, or portions of code. A computer program may be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs may instead include a number of sub-modules, third-party services, components, and libraries. Conversely, the features and functionality of various components may be combined into single components as appropriate. Thresholds used to make computational determinations may be statically, dynamically, or both statically and dynamically determined.

The methods, processes, or logic flows described in this specification may be performed by one or more programmable computers executing one or more computer programs to perform functions by operating on input data and generating output. The methods, processes, or logic flows may also be performed by, and apparatus may also be implemented as, special purpose logic circuitry, for example, a CPU, an FPGA, or an ASIC.

Computers suitable for the execution of a computer program may be based on one or more of general and special purpose microprocessors and other kinds of CPUs. The elements of a computer are a CPU for performing or executing instructions and one or more memory devices for storing instructions and data. Generally, a CPU may receive instructions and data from (and write data to) a memory. A computer may also include, or be operatively coupled to, one or more mass storage devices for storing data. In some implementations, a computer may receive data from, and transfer data to, the mass storage devices including, for example, magnetic, magneto-optical disks, or optical disks. Moreover, a computer may be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data may include all forms of permanent/non-permanent and volatile/non-volatile memory, media, and memory devices. Computer-readable media may include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media may also include, for example, magnetic devices such as tape, cartridges, cassettes, and internal/removable disks. Computer-readable media may also include magneto-optical disks and optical memory devices and technologies including, for example, digital video disc (DVD), CD-ROM, DVD+/−R, DVD-RAM, DVD-ROM, HD-DVD, and BLU-RAY. The memory may store various objects or data, including caches, classes, frameworks, applications, modules, backup data, jobs, web pages, web page templates, data structures, database tables, repositories, and dynamic information. Types of objects and data stored in memory may include parameters, variables, algorithms, instructions, rules, constraints, and references. Additionally, the memory may include logs, policies, security or access data, and reporting files. The processor and the memory may be supplemented by, or incorporated into, special purpose logic circuitry.

Implementations of the subject matter described in the present disclosure may be implemented on a computer having a display device for providing interaction with a user, including displaying information to (and receiving input from) the user. Types of display devices may include, for example, a cathode ray tube (CRT), a liquid crystal display (LCD), a light-emitting diode (LED), and a plasma monitor. Display devices may include a keyboard and pointing devices including, for example, a mouse, a trackball, or a trackpad. User input may also be provided to the computer through the use of a touchscreen, such as a tablet computer surface with pressure sensitivity or a multi-touch screen using capacitive or electric sensing. Other kinds of devices may be used to provide for interaction with a user, including to receive user feedback including, for example, sensory feedback including visual feedback, auditory feedback, or tactile feedback. Input from the user may be received in the form of acoustic, speech, or tactile input. In addition, a computer may interact with a user by sending documents to, and receiving documents from, a device that the user uses. For example, the computer may send web pages to a web browser on a user's client device in response to requests received from the web browser.

The term “graphical user interface,” or “GUI,” may be used in the singular or the plural to describe one or more graphical user interfaces and each of the displays of a particular graphical user interface. Therefore, a GUI may represent any graphical user interface, including, but not limited to, a web browser, a touch-screen, or a command line interface (CLI) that processes information and efficiently presents the information results to the user. In general, a GUI may include a plurality of user interface (UI) elements, some or all associated with a web browser, such as interactive fields, pull-down lists, and buttons. These and other UI elements may be related to or represent the functions of the web browser.

Implementations of the subject matter described in this specification may be implemented in a computing system that includes a back-end component, for example, as a data server, or that includes a middleware component, for example, an application server. Moreover, the computing system may include a front-end component, for example, a client computer having one or both of a graphical user interface or a Web browser through which a user may interact with the computer. The components of the system may be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network may communicate with, for example, Internet Protocol (IP) packets, frame relay frames, asynchronous transfer mode (ATM) cells, voice, video, data, or a combination of communication types between network addresses.

The computing system may include clients and servers. A client and server may generally be remote from each other and may typically interact through a communication network. The relationship of client and server may arise by virtue of computer programs running on the respective computers and having a client-server relationship.

Cluster file systems may be any file system type accessible from multiple servers for read and update. Locking or consistency tracking may not be necessary since the locking of exchange file system may be done at application layer. Furthermore, Unicode data files may be different from non-Unicode data files.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

While the various operations in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optionally” means that the subsequently described event or circumstances may or may not occur. The description includes instances where the event or circumstance occurs and instances where it does not occur.

As used, the term “determining” encompasses a wide variety of actions. For example, “determining” may include calculating, computing, processing, deriving, investigating, looking up (for example, looking up in a table, a database or another data structure), and ascertaining. Also, “determining” may include receiving (for example, receiving information) and accessing (for example, accessing data in a memory). Also, “determining” may include resolving, selecting, choosing, and establishing.

When the word “approximately” or “about” are used, this term may mean that there can be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do the words necessarily define a relative location or position of the component. Furthermore, it is to be understood that that the mere use of the term “first” and “second” does not require that there be any “third” component, although that possibility is contemplated under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. For example, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments shown herein, but are to be accorded the full scope consistent with the language of the claims.

What is claimed is:

1. A system comprising:
a memory containing computer-readable program code; and
a processor interoperably coupled to with the memory and configured to:
receive a substrate layout design comprising a substrate supplemental fill connection point and an associated chip group supplemental fill connection point;
pattern onto a substrate both the substrate supplemental fill connection point and the associated chip group supplemental fill connection point;
detect a disposition of the substrate supplemental fill connection point and the associated chip group supplemental fill connection point on the substrate;
determine a modified supplemental fill pixel model interconnection segment configured to couple the substrate supplemental fill connection point and the associated chip group supplemental fill connection point; and
pattern onto the substrate a modified supplemental fill interconnection segment such that the substrate supplemental fill connection point and the associated chip group supplemental fill connection point on the substrate are coupled based upon the modified supplemental fill pixel model interconnection segment.

2. The system of claim 1, wherein the memory comprises a table lookup function configured to select a predetermined supplemental fill pixel model interconnection based on a known disposition between a detected substrate supplemental fill connection point position and detected associated chip group supplemental fill connection point position to determine the modified supplemental fill pixel model interconnection.

3. The system of claim 2, further comprising:
training a trained ML model with the modified supplemental fill interconnection segment.

4. The system of claim 3, further comprising:
correlating the modified supplemental fill interconnection segment with the disposition of the substrate supplemental fill connection point and the associated chip group supplemental fill connection point on the substrate.

5. The system of claim 1, wherein the modified supplemental fill interconnection segment is independent from one or more connection elements of the substrate layout design.

6. The system of claim 1, wherein the modified supplemental fill interconnection segment comprises a repeating pattern.

7. A non-transitory tangible computer-readable storage medium having stored executable computer code, the computer code comprising a set of instructions that causes one or more processors to perform the following operations comprising:
receiving a substrate layout design comprising a substrate supplemental fill connection point and an associated chip group supplemental fill connection point;
pattering onto a substrate the substrate supplemental fill connection point and the associated chip group supplemental fill connection point;
detecting a disposition of the substrate supplemental fill connection point and the associated chip group supplemental fill connection point on the substrate;
determining a modified supplemental fill pixel model interconnection segment configured to couple the substrate supplemental fill connection point and the associated chip group supplemental fill connection point; and
patterning onto the substrate a modified supplemental fill interconnection segment such that the substrate supplemental fill connection point and the associated chip group supplemental fill connection point on the substrate are coupled based upon the modified supplemental fill pixel model interconnection segment.

8. The medium of claim 7, wherein:
the processors comprise a memory containing computer-readable program code and a trained machine learning (ML) model; and
determining the modified supplemental fill pixel model interconnection segment is performed by the trained ML model.

9. The medium of claim 8, wherein the memory comprises a table lookup function configured to select a predetermined supplemental fill pixel model interconnection based on a known disposition between a detected substrate supplemental fill connection point position and detected associated chip group supplemental fill connection point position to determine the modified supplemental fill pixel model interconnection.

10. The medium of claim 9, further comprising:
training the trained ML model with the modified supplemental fill interconnection segment.

11. The medium of claim 10, further comprising:
correlating the modified supplemental fill interconnection segment with the disposition of the substrate supplemental fill connection point and the associated chip group supplemental fill connection point on the substrate.

12. The medium of claim 11, further comprising:
storing the correlation of the modified supplemental fill interconnection segment in the table lookup function.

13. The medium of claim 7, wherein detecting the disposition of the substrate supplemental fill connection point and the associated chip group supplemental fill connection point on the substrate further comprises:
detecting a degree of misalignment of the substrate supplemental fill connection points and the associated chip group supplemental fill connection points;
and converting the degree of misalignment into displacement data, wherein the displacement data is used to determine the modified supplemental fill pixel model interconnection segment.

14. A computer-implemented method executed by one or more processors, the method comprising:
receiving a substrate layout design comprising a substrate supplemental fill connection point and an associated chip group supplemental fill connection point;
pattering onto a substrate the substrate supplemental fill connection point and the associated chip group supplemental fill connection point;
detecting a disposition of the substrate supplemental fill connection point and the associated chip group supplemental fill connection point on the substrate;
determining a modified supplemental fill pixel model interconnection segment configured to couple the substrate supplemental supplemental fill connection point and the associated chip group supplemental fill connection point; and
patterning onto the substrate a modified supplemental fill interconnection segment such that the substrate supplemental fill connection point and the associated chip group supplemental fill connection point on the substrate are coupled based upon the modified supplemental fill pixel model interconnection segment.

15. The method of claim 14, wherein the processors comprise a memory containing computer-readable program code and a trained machine learning (ML) model; and
determining the modified supplemental fill pixel model interconnection segment is performed by the trained ML model.

16. The method of claim 15, wherein the memory comprises a table lookup function configured to select a predetermined supplemental fill pixel model interconnection based on a known disposition between a detected substrate supplemental fill connection point position and detected associated chip group supplemental fill connection point position to determine the modified supplemental fill pixel model interconnection.

17. The method of claim 16, further comprising:
training the trained ML model with the modified supplemental fill interconnection segment.

18. The method of claim 17, further comprising:
correlating the modified supplemental fill interconnection segment with the disposition of the substrate supplemental fill connection point and the associated chip group supplemental fill connection point on the substrate.

19. The method of claim 18, further comprising:
storing the correlation of the modified supplemental fill interconnection segment in the table lookup function.

20. The method of claim 15, wherein detecting the disposition of the substrate supplemental fill connection point and the associated chip group supplemental fill connection point on the substrate further comprises:
detecting a degree of misalignment of the substrate supplemental fill connection points and the associated chip group supplemental fill connection points; and
converting the degree of misalignment into displacement data, wherein the displacement data is used to determine the modified supplemental fill pixel model interconnection segment.
